(19) United States
(12) Patent Application Publication
(10) Pub. No.: US 2006/0195761 A1
(43) Pub. Date: Aug. 31, 2006

(54) Method of generating low-density parity check matrix and method of generating parity information using the low-density parity check matrix

(75) Inventors: Hyun-jung Kim, Suwon-si (KR); Joo-ho Kim, Yongin-si (KR); Kyung-geun Lee, Seongnam-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/348,379

(22) Filed: Feb. 7, 2006

(30) Foreign Application Priority Data
Feb. 26, 2005 (KR) 2005-16263

(51) Int. Cl. H03M 13/00

(52) U.S. Cl. 714/758

(57) ABSTRACT

A method of generating a parity check matrix and a method of generating parity information using the parity check matrix, wherein the method of generating a parity check matrix includes selecting elements of a low-density parity check (LDPC) matrix such that every element of a top right corner portion of a Richardson matrix is 0. In the selection of the elements of the LDPC matrix, two unit matrices of m/2*m/2 are arranged in a top portion of a portion corresponding to parity information in the LDPC matrix and elements of two matrices located below the two unit matrices are selected such that every element of the top right corner portion of the sum of the two matrices is 0.

### CROSS-REFERENCE TO RELATED APPLICATION

This application claims the benefit of Korean Patent Application No. 2005-16263, filed on Feb. 26, 2005 in the Korean Intellectual Property Office, the disclosure of which is incorporated herein in its entirety by reference.

### BACKGROUND OF THE INVENTION

1. Field of the Invention

An aspect of the present invention relates to a method of generating a parity check matrix and a method of generating parity information using the parity check matrix, and more particularly, to such methods in which inverse matrix calculation is not required in the generation of parity information.

2. Description of the Related Art

FIG. 1 shows the concept of a low-density parity check (LDPC) coding and decoding method.

To generate additional information for error correction, an LDPC coding method is widely used. LDPC coding involves generating parity information using an LDPC matrix H composed of 0s and 1s, in which the number of 1s is far less than the number of 0s.

The number of 1 s included in each row or column of a parity check matrix is referred to as a row degree or a column degree. A regular parity check matrix is a parity check matrix in which all the row degrees are the same and all the column degrees are the same. An irregular parity check matrix is a parity check matrix in which all the row degrees are not the same and all the column degrees are not the same. In a regular parity check matrix, a row degree is referred to as a row weight (Wr) and a column degree is referred to as a column weight (Wc).

The generation of parity information using LDPC coding is performed using Equation 1 (which will be referred to as a parity check equation).
HX=0 (1),

where H represents a parity check matrix of m*n and X represents a codeword matrix of n*1. X is composed of m message information and p parity information. Thus, m+p=n.

The basic concept of LDPC coding has been disclosed by D. J. MacKay in “Good Error-Correction Codes Based on Very Sparse Matrices” (IEEE Trans. on Information Theory, vol. 45, no.2, pp. 399-431, 1999). According to this paper, parity information can be generated by calculating Equation 1 using a matrix operation such as Gaussian elimination.

Since LDPC coding uses a large code length and the size of parity check matrix H is large, encoding using Gaussian elimination requires very complicated computation. To solve this problem, an efficient encoding method has been developed by T. J. Richardson for transforming a parity check matrix into another format (referred to as the Richardson method).

FIG. 2 illustrates the format of a parity check matrix that is transformed through the Richardson method.

According to the Richardson method, a parity check matrix H is transformed into a transformed parity check matrix H′ through row interchange and column interchange. At this time, the top right corner portion of the transformed parity check matrix H′ should be composed of only 0s, as shown in FIG. 2. In other words, the transformed parity check matrix H′ is composed of blocks A, B, C, D, E, and T, and the top right corner of the block T is composed of only 0s.

According to the Richardson method, since every element of the top right corner portion of the transformed parity check matrix H′ is 0, 1 parity information can be easily obtained through back substitution, which aids the generation of parity information. However, to obtain (m-1) parity information, inverse matrix calculation is required. The remaining (m-1) parity information can be obtained as follows.

Equation 1 is transformed into Equation 2 through the Richardson method.

$$Hx = {H}^{′} x = [ \begin{matrix}A & B & T \\ C & D & E\end{matrix} ] [ \begin{matrix}S \\ {P}_{1} \\ {P}_{2}\end{matrix} ] , \qquad ( 2 )$$

where S represents a message information vector and P₁ and P₂ respectively represent a first parity information vector and a second parity information vector of m/2.

Equation 2 is expressed as matrix equations like Equations 3 and 4.
AS+BP₁+TP₂=0 (3)
(−ET⁻¹A+C)S+(−ET⁻¹B+D)P₁=(−ET⁻¹A+C)S+QP₁=0 (4),

where a Richardson matrix Q=(−ET⁻¹B+D). By combining Equations 3 and 4, parity information P₁ and P₂ can be obtained as Equations 5 and 6.
P₁=−(−ET⁻¹B+D)⁻¹(−ET⁻¹A+C)S=−Q⁻¹(−ET⁻¹A+C)S (5)
P₂=−T⁻¹(AS+BP₁) (6)

According to the Richardson method, although 1 parity information can easily be obtained through back substitution, an inverse matrix Q-1 must be calculated to obtain the remaining m-1 parity information, which needs much calculation.

### SUMMARY OF THE INVENTION

According to an aspect of the present invention, there is provided a method of generating a parity check matrix and a method of generating parity information using the parity check matrix, by which the amount of calculation is reduced in LDPC coding using a parity check matrix.

According to another aspect of the present invention, there is provided a method of generating an m*n low-density parity check (LDPC) matrix. The method includes selecting elements of the LDPC matrix such that every element of the top right corner portion of a Richardson matrix is 0.

According to another aspect of the present invention, the selection of the elements of the LDPC matrix includes arranging two unit matrices of m/2*m/2 in the top portion of a portion corresponding to parity information in the LDPC matrix and selecting elements of two matrices located below the two unit matrices such that every element of the top right corner portion of the sum of the two matrices is 0.

According to another aspect of the present invention, the selection of the elements of the two matrices includes selecting a first matrix in which every element of the top right corner is 0 and every element in a cross line of the bottom left portion is 1, and selecting a second matrix whose elements which are 1s do not overlap with the first matrix and which satisfies all the conditions for the first matrix.

According to another aspect of the present invention, there is provided a method of generating parity information using a low-density parity check (LDPC) matrix. The method includes generating two equations for a first parity information vector having a length of m/2 and a second parity information vector having a length of m/2 using a parity check equation composed of an m*n LDPC matrix and an n*1 codeword matrix and calculating first parity information by applying back substitution to the equation for the first parity information vector. In the m*n LDPC matrix, every element of the top right corner of a Richardson matrix is 0.

According to another aspect of the present invention, in the m*n LDPC matrix, two unit matrices of m/2*m/2 are arranged in the top portion of a portion corresponding to parity information and every element of the top right corner portion of the sum of two matrices located below the two unit matrices is 0.

According to another aspect of the present invention, the generation of the two equations includes selecting a first matrix in which every element of the top right corner is 0 and every element in a cross line of the bottom left portion is 1, and selecting a second matrix whose elements which are is do not overlap with the first matrix and which satisfies all the conditions for the first matrix.

According to another aspect of the present invention, the calculation of the first parity information is performed using
(M₂A+C)S+(M₁+M₂)P₁=0,

where M₁ and M₂ represent the first matrix and the second matrix that are located below the two unit matrixes, P₁ represents the first parity information vector, S represents a message information vector, A represents a matrix corresponding to a portion that is located on the left side of the two unit matrices in the LDPC matrix, and C represents a matrix corresponding to a portion that is located on the left side of the two matrices that is located below the two unit matrices in the LDPC matrix.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 shows the concept of an LDPC coding and decoding method;

FIG. 2 illustrates the format of a parity check matrix that is transformed through a Richardson method;

FIG. 3 illustrates a parity check matrix according to an embodiment of the present invention;

FIGS. 4 and 5 illustrate examples of matrices M₁, M₂, and M₁+M₂ according to an embodiment of the present invention;

FIG. 6 is a flowchart illustrating a method of calculating a first parity information vector P₁ using back substitution;

FIG. 7 is a flowchart illustrating a method of generating a parity check matrix according to an embodiment of the present invention; and

FIG. 8 is a flowchart illustrating a method of generating parity information using an LDPC matrix according to an embodiment of the present invention.

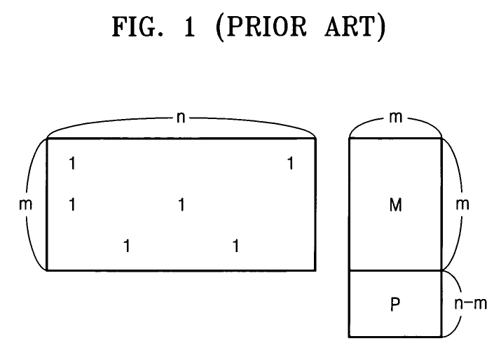

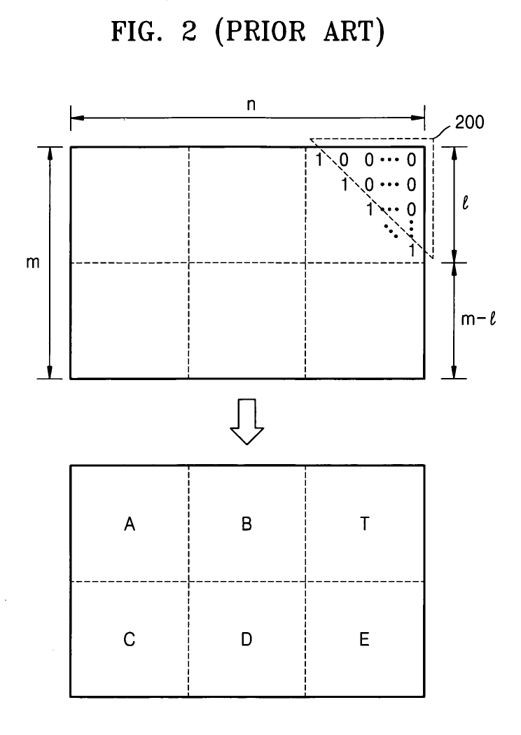

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

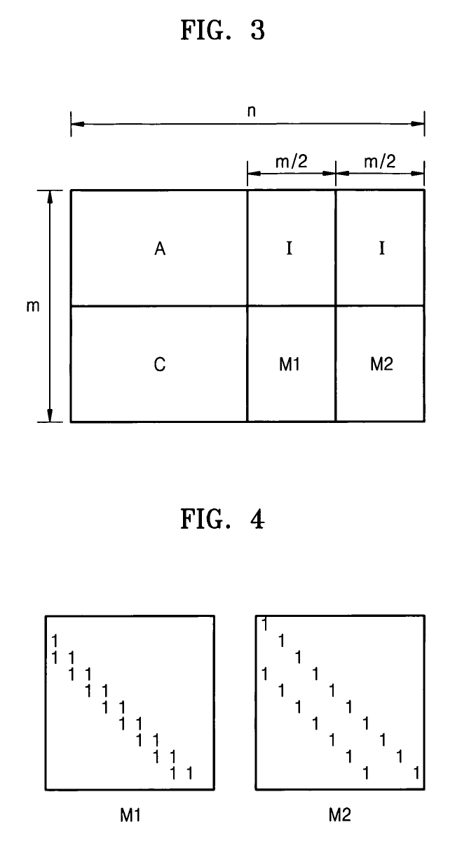

FIG. 3 illustrates a parity check matrix according to an embodiment of the present invention.

The parity check matrix according to an embodiment of the present invention can be generated by selecting elements for the parity check matrix, i.e., matrices E, T, B, and D, such that every element of all the matrices of the top right corner portion of the Richardson matrix Q in Equation 4 is 0. In other words, a condition for the parity check matrix to achieve the effect of an embodiment of the present invention is that every element of all the matrices of the top right corner portion of the Richardson matrix Q be 0. The parity check matrix shown in FIG. 3 satisfies this condition.

Referring to FIG. 3, a parity check matrix H is generated to meet the following conditions.

(Condition 1) The top left matrix and the top right matrix corresponding to the first parity information vector P₁ and the second parity information vector P₂ in Equation 1 are unit matrices I. The first parity information vector P₁ and the second parity information vector P₂ represent the top half and the bottom half of m parity information included in the codeword matrix X of Equation 1.

(Condition 2) In the sum of the bottom left matrix M₁ and the bottom right matrix M₂, i.e., a sum matrix M₁+M₂, every element of the top right corner portion is 0.

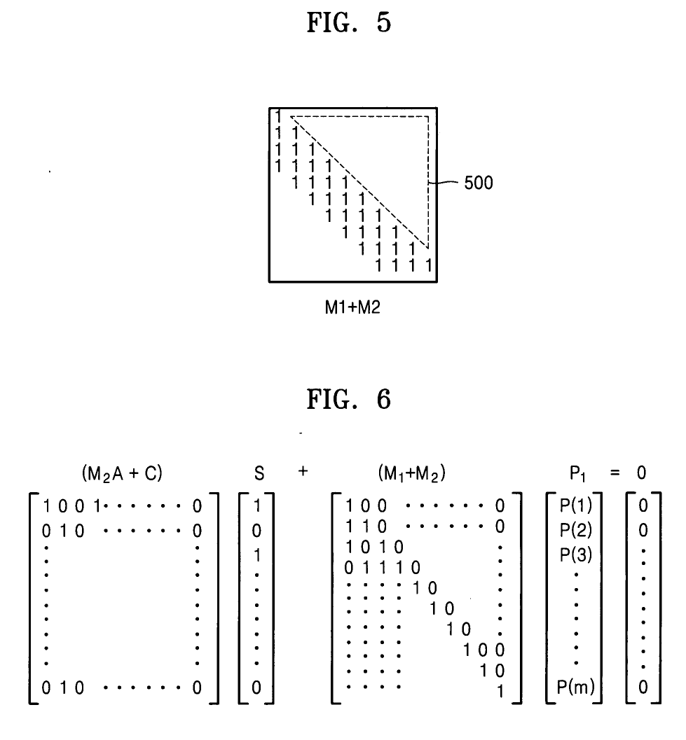

FIGS. 4 and 5 illustrate examples of the matrices M₁, M₂, and M₁+M₂ according to an embodiment of the present invention.

As shown in FIG. 4, the matrix M₁ is a 10*10 matrix in which elements in a line connecting the position (2,1) and the position (10,9) and a line connecting the position (3,1) and the position (10,8) are all 1s, and the other elements are all 0s. The matrix M₂ is a 10*10 matrix in which elements in a line connecting the position (1,1) and the position (10,10) and a line connecting the position (4,1) and the position (10,7) are all 1s, and the other elements are all 0s.

The sum matrix M₁+M₂ is as shown in FIG. 5, and all the elements of the top right corner portion 500 of the sum matrix M₁+M₂ are 0s.

Hereinafter, a description will be made regarding how the amount of calculation can be reduced when parity information is generated using the parity check matrix of FIG. 3.

According to the parity check matrix as shown in FIG. 3, Equation 1 for generating the first parity information vector P₁ and the second parity information vector P₂ can be expressed as follows.
AS+P₁+P₂=0 (7)
CS+M₁P₁+M₂P₂=0 (8)

Equations 7 and 8 can be arranged as follows.
P₂=−(AS+P₁) (9)
(M₂A+C)S+(M₁+M₂)P₁=0 (10)

Referring to Equations 9 and 10, the first parity information vector P₁ can be calculated using Equation 10 and the second parity information vector P₂ can be calculated using Equation 9. At this time, since the sum matrix M₁+M₂ has a structure as shown in FIG. 5, the first parity information vector P₁ can be easily generated using back substitution. Thus, since inverse matrix calculation is not required in the calculation of the first parity information vector P₁, the overall amount of calculation is reduced in the generation of parity information.

FIG. 6 is a flowchart illustrating a method of calculating the first parity information vector P₁ using back substitution.

To obtain the first parity information vector P₁, Equation 10 must be calculated. In Equation 10, since all information other than the first parity information vector P₁ is already known, the first parity information vector P₁ can be obtained by calculating Equation 10 with respect to the first parity information vector P₁.

A first simultaneous equation in a matrix equation of FIG. 6 is as follows.
a1+p(1)=0 (11),

where a1 represents the product of multiplying the first row of a matrix (M₂A+C) and a message information vector S, and p(1) represents first parity information of the first parity information vector P₁. p(1) can be obtained using Equation 11.

Similarly, a second simultaneous equation in the matrix equation of FIG. 6 is as follows.
a2+p(1)+p(2)=0 (12),

where a2 represents the product of multiplying the second row of the matrix (M₂A+C) and the message information vector S. Since p(1) is obtained using Equation 11, p(2) can be easily obtained. In other words, p(2) can be obtained using Equations 11 and 12.

Similarly, a third simultaneous equation in the matrix equation of FIG. 6 is as follows.
a3+p(1)+p(3)=0 (13),

where a3 represents the product of multiplying the third row of the matrix (M₂A+C) and the message information vector S. Since p(1) is obtained using Equation 11, p(3) can be easily obtained. In other words, p(3) can be obtained using Equations 11 and 13.

The calculation of Equations 11 through 13 is repeated until mₜₕ parity information p(m) is obtained. In other words, by calculating m simultaneous equations such as Equations 11 through 13, parity information p(1), p(2), . . . , p(m) can be sequentially obtained.

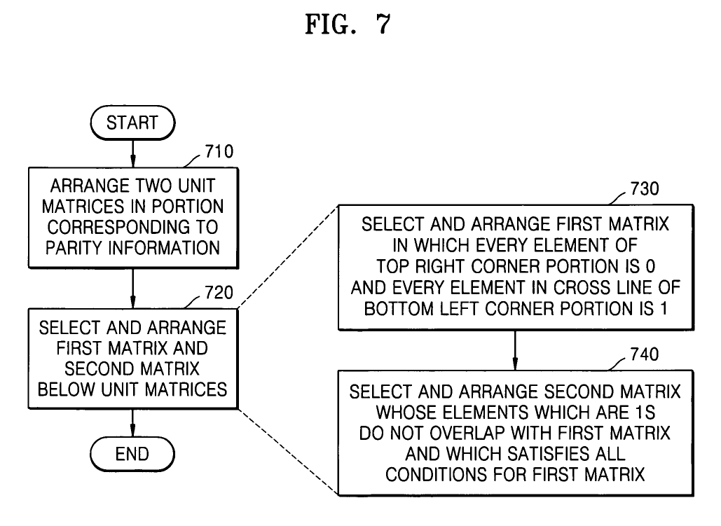

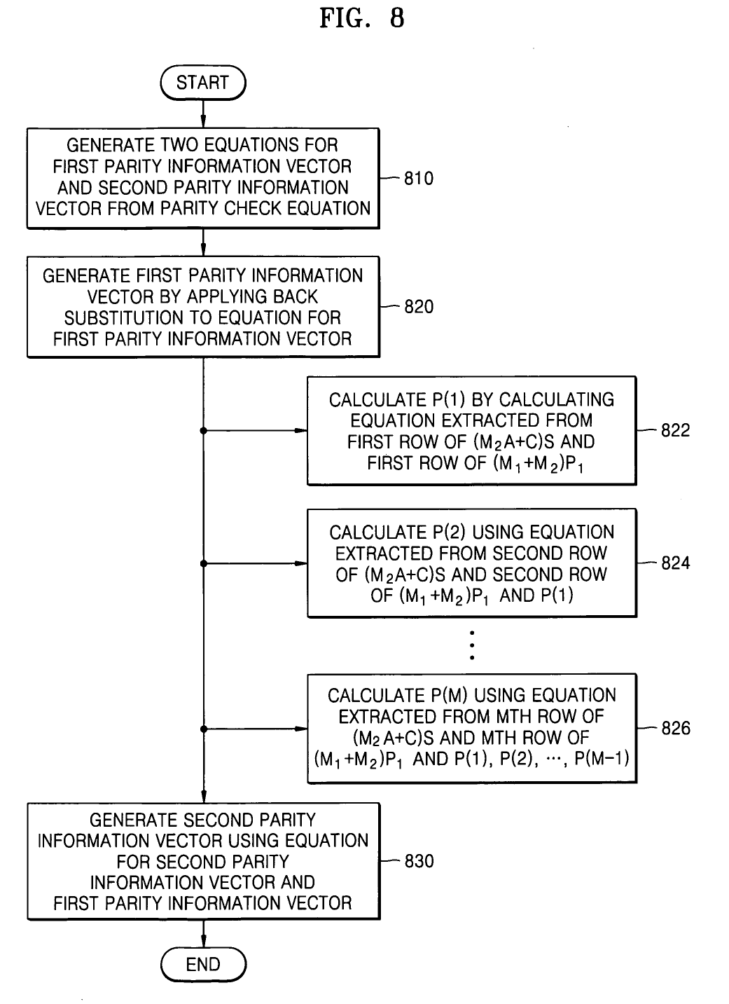

FIG. 7 is a flowchart illustrating a method of generating a parity check matrix according to an embodiment of the present invention.

In operation 710, two unit matrices of m/2*m/2 are arranged in a top portion corresponding to parity information in an m*n parity check matrix.

In operation 720, elements for a first matrix and a second matrix that are located below the two unit matrices arranged in operation 710 are selected and arranged such that the sum of the first matrix and the second matrix has a top right corner portion whose elements are all 0s.

According to an embodiment of the present invention, operation 720 includes operations 730 and 740.

In operation 730, the first matrix in which every element of the top right corner portion is 0 and every element in a cross line of the bottom left corner portion is 1 is selected and arranged.

In operation 740, the second matrix whose elements which are 1s do not overlap with the first matrix and which satisfies all the conditions for the first matrix is selected. In other words, the second matrix in which elements which are 1s do not overlap with the first matrix, every element of the top right corner portion is 0, and every element in a cross line of the bottom left corner portion is 1 is selected and arranged.

According to another embodiment of the present invention, operation 720 includes selecting the first matrix and the second matrix to prevent a four-cycle phenomenon. The four-cycle phenomenon indicates degradation in the BER performance of decoding when an element 1 included in a parity check matrix is located at a specific position. The specific position is a position corresponding to four vertexes of a square in a parity check matrix, e.g., (2,2), (2,8), (4,8), and (4,2). Thus, in operation 720, the first matrix and the second matrix are selected such that elements at four vertexes of a portion of a parity check matrix are not 1.

FIG. 8 is a flowchart illustrating a method of generating parity information using an LDPC matrix according to an embodiment of the present invention.

In operation 810, two equations for a first parity information vector having a length of m/2 and a second parity information vector having a length of m/2, i.e., Equations 9 and 10, are obtained using a parity check equation including an m*n LDPC matrix H and an n*1 codeword matrix M, i.e., Equation 1.

Here, the LDPC matrix H is selected such that two unit matrices of m/2*m/2 are arranged in a top portion corresponding to parity information, and every element of the top right portion of the sum of two matrices located below the unit matrices is 0.

Operation 810 includes calculating matrices (M₂A+C)S and (M₁+M₂)P₁.

In operation 820, first parity information is calculated by applying back substitution to Equation 10 obtained in operation 810. Operation 820 includes operations 822 and 824.

In operation 822, first parity information p(1) of a first parity information vector is calculated by calculating an equation extracted from the first row of the matrix (M₂A+C)S and the first row of the matrix (M₁+M₂)P₁, e.g., Equation 11.

In operation 824, second parity information of the first parity information vector is calculated using an equation extracted from the second row of the matrix (M₂A+C)S and the second row of the matrix (M₁+M₂)P₁ and the first parity information.

In operation 826, mth parity information of the first parity information vector is calculated using an equation extracted from the mₜₕ row of the matrix (M₂A+C)S and the mₜₕ row of the matrix (M₁+M₂)P₁ and first through (m-1)ₜₕ parity information, thereby generating the first parity information vector.

In operation 830, a second parity information vector is generated using an equation for the second parity information vector, i.e., Equation 9, and the first parity information vector generated in operation 820.

As described above, according to an embodiment of the present invention, since inverse matrix calculation is not required, parity information can be easily generated.

The method of generating a parity check matrix and a method of generating parity information using the parity check matrix according to an embodiment of the present invention can also be embodied as computer readable code on a computer readable recording medium. Code and code segments forming the computer program can be easily construed by computer programmers skilled in the art. Also, the computer program can be stored in computer readable media and read and executed by a computer, thereby implementing the method of generating a parity check matrix and the method of generating parity information using the parity check matrix. Examples of the computer readable media include magnetic tapes, optical data storage devices, and carrier waves.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of generating an m*n low-density parity check (LDPC) matrix, the method comprising;
selecting elements of the LDPC matrix such that every element of a top right corner portion of a Richardson matrix is 0.

2. The method of claim 1, wherein the selecting of the elements of the LDPC matrix comprises:
arranging two unit matrices of m/2*m/2 in a top portion of a portion corresponding to parity information in the LDPC matrix; and
selecting elements of two matrices located below the two unit matrices such that every element of the top right corner portion of a sum of the two matrices is 0.

3. The method of claim 2, wherein the selecting of the elements of the two matrices comprises:
selecting a first matrix in which every element of a top right corner is 0 and every element in a cross line of a bottom left portion is 1; and
selecting a second matrix whose elements which are 1 s do not overlap with the first matrix, every element of a top right corner portion is 0, and every element in a cross line of a bottom left corner portion is 1.

4. The method of claim 3, wherein the selecting of the elements of the two matrices comprises selecting the first matrix and the second matrix to prevent a 4-cycle phenomenon.

5. A method of generating parity information using a low-density parity check (LDPC) matrix, the method comprising:
generating a first equation for calculating a first parity information vector having a length of m/2 and generating a second equation for calculating a second parity information vector having a length of m/2, using a parity check equation composed of an m*n LDPC matrix and an n*1 codeword matrix; and
calculating first parity information by applying back substitution to the first equation,
wherein in the m*n LDPC matrix, every element of a top right corner of a Richardson matrix is 0.

6. The method of claim 5, wherein in the m*n LDPC matrix, two unit matrices of m/2*m/2 are arranged in z top portion of a portion corresponding to parity information, and every element of z top right corner portion of z sum of two matrices located below the two unit matrices is 0.

7. The method of claim 6, wherein the generating of the first and second equations comprises:
selecting a first matrix in which every element of a top right corner is 0 and every element in a cross line of a bottom left portion is 1; and
selecting a second matrix whose elements which are 1 s do not overlap with the first matrix, every element of a top right corner portion is 0, and every element in a cross line of the bottom left corner portion is 1.

8. The method of claim 7, wherein the generating of the first and second equations comprises selecting the first matrix and the second matrix to prevent a 4-cycle phenomenon.

9. The method of claim 6, further comprising calculating the second parity information vector using the second equation and the calculated first parity information vector.

10. The method of claim 7, wherein calculating the first parity information is performed using
(M₂A+C)S+(M₁+M₂)P₁=0,
where M₁ and M₂ represent the first matrix and the second matrix that are located below the two unit matrices, P₁ represents the first parity information vector, S represents a message information vector, A represents a matrix corresponding to a portion of the LPDC matrix that is located on a left side of the two unit matrices in the LDPC matrix, and C represents a matrix corresponding to a portion of the LDPC matrix that is located on the left side of the first and second matrices.

11. The method of claim 10, wherein the calculating of the first parity information further comprises:
calculating the first parity information of the first parity information vector by calculating an equation extracted from a first row of (M₂A+C)S and a first row of (M₁+M₂)P₁; and
calculating second parity information of the first parity information vector by using an equation extracted from a second row of (M₂A+C)S and a second row of (M₁+M₂)P₁ and the calculated first parity information.

12. A computer-readable recording medium having recorded thereon a program for implementing the method of claim 5.

13. The method of claim 3, wherein the first matrix and the second matrix are selected such that elements at four vertexes of a portion of the LPDC matrix are not 1.

14. The method of claim 7, wherein the first matrix and the second matrix are selected such that elements at four vertexes of a portion of the LPDC matrix are not 1.

15. A method of generating an m*n low-density parity check (LDPC) matrix, the method comprising:
arranging two unit matrices of m/2*m/2 in a top portion corresponding to parity information in the m*n LDPC matrix; and
selecting and arranging elements of a first matrix and a second matrix that are located below the two unit matrices such that a sum of the first matrix and the second matrix have a top right corner portion whose elements are all 0s.

16. The method of claim 15, wherein the selection and arranging of the elements of the first matrix comprises selecting the first matrix in which every element of a top right corner portion is 0 and every element in a cross line of the bottom left corner portion is 1.

17. The method of claim 15, wherein the selection and arranging of the elements of the second matrix comprises selecting a second matrix whose elements which are 1s do not overlap with the first matrix, every element of a top right corner portion is 0, and every element in a cross line of a bottom left corner portion is 1.

18. The method of claim 15, wherein the first matrix and the second matrix are selected such that elements at four vertexes of a portion of the LPDC matrix are not 1.

19. The method of claim 15, wherein no inverse matrix calculation is performed.
